(19) United States
(12) Patent Application Publication
(10) Pub. No.: US 2015/0053257 A1
(43) Pub. Date: Feb. 26, 2015

(54) MULTI-JUNCTION SOLAR CELL AND USE THEREOF

(71) Applicant: FRAUNHOFER-GESELLSCHAFT ZUR FÖRDERUNG DER ANGEWANDTEN FORSCHUNG E.V., München (DE)

(72) Inventors: Frank Dimroth, Freiburg (DE); Andreas Bett, Freiburg (DE)

(21) Appl. No.: 14/383,458

(22) PCT Filed: Mar. 8, 2013
(86) PCT No.: PCT/EP2013/054754

§ 371 Date: Sep. 5, 2014

(30) Foreign Application Priority Data
Mar. 8, 2012 (DE) 10 2012 004 734.7

(51) Int. Cl. H01L 31/0725; H01L 31/0232; H01L 31/18; H01L 31/074; H01L 31/0216

(52) U.S. Cl. CPC H01L 31/0725; H01L 31/074; H01L 31/02167; H01L 31/18; H01L 31/02168; H01L 31/02327
USPC 136/255; 438/74

(57) ABSTRACT

The present invention relates to a multi junction solar cell having at least four p-n junctions. The individual subcells thereby have band gaps of 1.9 eV, 1.4 eV, 1.0 eV and 0.7 eV. The multi junction solar cells according to the invention are used in space and also in terrestrial concentrator systems.

The present invention relates to a multi junction solar cell having at least four p-n junctions. The individual partial cells thereby have band gaps of 1.9 eV, 1.4 eV, 1.0 eV and 0.7 eV. The multi junction solar cells according to the invention are used in space and also in terrestrial concentrator systems.

It is known that so-called multi junction solar cells profit if the number of subcells can be increased. However, in addition to the number of subcells, the so-called band gap energies of the materials are thereby important. These must be adapted optimally to the solar spectrum. The best solar cells today consist of three p-n junctions in the materials gallium-indium-phosphide (GaInP), gallium-indium-arsenide (GaInAs) and germanium. The materials can be grown adapted lattice-wise to each other.

It has been known for a long time that the efficiency of these solar cells can be increased significantly by an additional subcell being inserted between the GaInAs subcell and the germanium subcell. This subcell should ideally have a band gap energy of approx. 1.0 eV. It is problematic that no known semiconductor with high material quality and with the lattice constant of gallium arsenide (GaAs) or germanium fulfils this requirement. For this reason, nowadays a large number of new manufacturing methods and concepts are being discussed in order to solve this problem. There are included herein
concepts in which the solar cell structure is grown in inverted sequence,
concepts in which the solar cell structure is constructed on a different lattice constant,
concepts in which new materials such as thinned nitrides are used and also
concepts in which wafer bonding is used.

It is therefore the objective in the state of the art to develop a quadruple solar cell having optimum band gap energy for the AM1.5 or AM0 solar spectrum. The optimum band gap energies are thereby in the range of: 1.9 eV/1.4 eV/1.0 eV/0.7 eV.

There are various approaches to the production of such III-V multi junction solar cells having four p-n junctions. The most important are intended to be explained briefly in the following:

### 1. GaInP/GaInAs/GaInNAs/Ge Solar Cell:

This type of quadruple solar cell is built on the conventional epitaxy of III-V multi junction solar cells on a germanium substrate. The only difference from the present state of the art is the integration of an additional subcell made of the thinned nitrogen-containing material gallium-indium-nitride-arsenide (GaInNAs). As an alternative to GaInNAs, also semiconductors such as gallium-nitride-arsenide-antimonide (GaNAsSb) or boron-gallium-indium-arsenide (BGaInAs) can be used. The concentration of N or B is in the range of 2-4%. Thus III-V compounds which have a band gap energy of 1.0 eV can be produced and can be grown adapted lattice-wise to germanium. The major problem in this approach is the material quality of the thinned N- (or B)-containing materials. To date, it has not been possible to produce solar cells with high efficiency and, at the same time, with the currently widespread method of organometallic vapour phase epitaxy. However, good results were achieved with growth by means of molecular beam epitaxy. This method is however distinguished by significantly higher production costs for the solar cells and therefore is not used nowadays in industrial production. Growth of the GaInP/GaInAs/GaInNAs/Ge solar cells by means of organometallic vapour phase epitaxy is at present not foreseeable. In publications by Volz et al. and Friedman et al., solar cells of this type are described (Volz, K. et al., Optimization of annealing conditions of (GaIn)(NAs) for solar cell applications, Journal of Crystal Growth, 2008, 310 (7-9): p. 2222-8 and also Volz et al., Development and optimization of a 1 eV (GaIn)(NAs) solar cell, in Proceedings of the 34^{th} IEEE Photovoltaic Solar Energy Conference, 2009, Philadelphia, USA and also Friedman, D. J., et al. 0.7-eV GaInAs Junction for a GaInP/GaAs/GaInAs (1 eV)/GaInAs (0.7 eV) Four-Junction Solar Cell, in Proceedings of the 4^{th} World Conference on Photovoltaic Energy Conversion, 2006, Waikoloa, Hi., USA).

### 2. GaInP/GaAs/GaInAsP/GaInAs Solar Cell:

In the case of this type of quadruple solar cell, the one half of the structure is grown on a gallium arsenide substrate and the other half on an indium-phosphide substrate. In principle, the desired band gaps of the materials can be achieved. In this concept, the upper and lower part of the structure are connected via a wafer bonding or via mechanical stacking The disadvantage of this structure resides in the fact that the lower subcell must be grown on an indium-phosphide substrate. This substrate is extremely expensive (the costs are approx. 8-10 times higher compared with germanium and gallium arsenide). In the publication by Bhusari et al., solar cells of this type are described (Bhusari, D., et al., Direct semiconductor bonding technology (SBT) for high efficiency III-V multi-junction solar cells, in Proceedings of the 37^{th} IEER Photovoltaic Specialists Conference, 2011, Seattle, Wash., USA).

### 3. Inverted GaInP/GaAs/GaInAs/GaInAs Solar Cell:

In this concept, all the subcells are grown inverted on a gallium arsenide- or germanium substrate. Thereafter, the structure is transferred onto a substrate for stabilisation, the gallium arsenide- or germanium substrate is removed and the solar cell is processed. The low band gap energies of GaInAs in the range of 1.0 eV and 0.7 eV require growth of metamorphic buffer layers with very high distortion. As a result, numerous offsets occur which have an effect on the efficiency of the solar cell. Furthermore, it has emerged that the GaInAs material is less suitable for space application since the solar cells degrade faster with irradiation with high-energy electrons and protons. In Friedman et al., solar cells of this type are described (Friedman, D. J., et al, 0.7-eV GaInAs Junction for a GaInP/GaAs/GaInAs (1 eV)/GaInAs (0.7 eV) Four-Junction Solar Cell, in Proceedings of the 4^{th} World Conference on Photovoltaic Energy Conversion, 2006, Waikoloa, Hi., USA).

Starting herefrom, it was the object of the present invention to provide a method for the production of multi junction solar cells which is easy to implement and can be combined with conventional epitaxial methods. At the same time, the multi junction solar cells according to the invention are intended to have band gaps of 1.9 eV, 1.4 eV, 1.0 eV and 0.7 eV and thereby should show an improved radiation stability at the same time.

This object is achieved by the multi junction solar cell having the features of claim 1, the method for the production of the multi junction solar cell having the features of claims 11 to 13. The further dependent claims reveal advantageous developments. In claim 15, uses according to the invention of the multi junction solar cell are mentioned.

According to the invention, a multi junction solar cell having at least four p-n junctions is provided, comprising a first, rear-side germanium subcell which has a p-n junction, a second and a third subcell made of III-V semiconductors and also at least one further, front-side subcell made of III-V semiconductors.

A multi junction solar cell according to the invention is distinguished by the second subcell having a lattice constant which is greater by at least 1% than the lattice constants of all the other subcells and the second subcell being connected to the adjacent subcells via a metamorphic buffer layer for adaptation to the lattice constants of the adjacent subcells and, on the opposite side of the second subcell, being connected to the adjacent subcell via a wafer-bonding connection.

A further embodiment according to the invention relates to a multi junction solar cell having at least four p-n junctions, comprising a first, rear-side germanium subcell which has a p-n junction, a second and a third subcell made of III-V semiconductors and also at least one further, front-side subcell made of III-V semiconductors, which is characterised in that the second subcell has a lattice constant which is greater by at least 1% than the lattice constant of all the other subcells and the second subcell is connected to the adjacent germanium subcell via a metamorphic buffer layer for adaptation to the lattice constant of the adjacent subcells and, on the opposite side, is connected to the adjacent cells via a wafer-bonding connection.

According to the invention, a multi junction solar cell can hence be provided by combination of epitaxial growth on two different substrates, metamorphic growth and wafer bonding. Three of the p-n junctions in this structure are junctions adapted lattice-wise to the germanium- or gallium-arsenide subcell since both crystals have a very similar lattice constant. These three p-n junctions are the front-side subcell, the third subcell and the rear-side germanium subcell. Between these subcells, a further subcell (the second subcell) with a band gap energy of 1.0 eV is now inserted. This second subcell has a significantly greater lattice constant in comparison with the materials of the other subcells. For incorporation of the second subcell in the multi junction solar cell, it is necessary that the lattice constant is changed, with the help of a metamorphic buffer, gradually from the lattice constant of the third subcell (e.g. GaAs) to the lattice constant of the second subcell (e.g. GaInAs) or from the lattice constant of the first subcell (e.g. Ge) to the lattice constant of the second subcell (e.g. GaInAs).

Preferably, the second subcell consists of gallium-indium-arsenide (GaInAs), gallium-arsenide-antimonide (GaAsSb), gallium-indium-arsenide-phosphide (GaInAsP) or aluminium-gallium-indium-arsenide (AlGaInAs). For particular preference, it hereby concerns a GaInAs subcell.

If the second subcell concerns a subcell comprising indium, then the content of indium, relative to the total content of III semiconductors, is preferably in the range of 10 to 80% by weight, particularly preferred in the range of 20 to 50% by weight.

If the second subcell concerns a subcell comprising antimony, then the content of antimony, relative to the total content of V semiconductors, is preferably in the range of 13 to 50% by weight.

Preferably, the second subcell has a band gap energy between 0.7 eV and 1.4 eV, particularly preferred between 0.9 eV and 1.1 eV. The most optimal results can be achieved with a second subcell having a band gap energy of 1.0 eV.

A further preferred embodiment provides that the second subcell has a lattice constant which is greater by at least 1%, preferably by 2 to 2.5%, than the lattice constants of all the other subcells.

The metamorphic buffer layer preferably consists of gallium-indium-antimonide (GaInAs), aluminium-gallium-indium-arsenide (AlGaInAs), gallium-indium-phosphide (GaInP), aluminium-gallium-indium-phosphide (AlGaInP), gallium-arsenide-antimonide (GaAsSb), aluminium-arsenide-antimonide (AlAsSb), gallium-phosphide-antimonide (GaPSb) or aluminium-phosphide-antimonide (AlPSb) and can be configured, respectively according to the position of the tunnel diodes, to be either p- or n-conducting, the lattice constant being converted by a plurality of steps or continuously from the lattice constant of the third subcell (e.g. GaAs) to the lattice constant of the second subcell (e.g. GaInAs) or from the lattice constant of the first subcell (e.g. Ge) to the lattice constant of the second subcell (e.g. GaInAs).

It is further preferred that the wafer-bonding connection between the relevant subcells is electrically conductive and optically transparent. There is understood by optical transparency within the scope of the present invention, a transmission of at least 80%, preferably of at least 95%, at wavelengths of at least 900 nm.

The wafer-bonding connection can be effected, respectively according to the position of the tunnel diodes, between two p-conducting or two n-conducting semiconductor layers which preferably have high doping.

With respect to the further subcells, basically all the materials known in the state of the art which fulfil the specifications with respect to band gap energy can be used.

The third subcell preferably consists of gallium-arsenide (GaAs), gallium-indium-arsenide (GaInAs) or aluminium-gallium-indium-arsenide (AlGaInAs). The at least one further, front-side subcell preferably consists of gallium-indium-phosphide (GaInP), aluminium-gallium-arsenide (AlGaAs) or aluminium-gallium-indium-phosphide (AlGaInP) or essentially comprises these.

Preferably, a multi junction solar cell having four subcells is provided, the fourth subcell representing a front-side subcell. However it is likewise also possible that one or further subcells are disposed between the front-side subcell and the third subcell, from which then multi junction solar cells having five or more subcells can result.

It is further preferred that the individual subcells have further function-protection layers, in particular tunnel diodes for the electrical connection of the individual subcells, barrier layers on the front- and rear-side of the subcells, highly doped contact layers, internal reflection layers and/or anti-reflection layers on the front-side of the cell.

According to the invention, likewise methods for the production of the previously described multi junction solar cells are provided. There are hereby basically three different approaches:

1. On the first germanium subcell, the metamorphic buffer layer and second subcell are grown. Subsequently, separately herefrom on a GaAs- or Ge substrate, the third subcell made of III-V semiconductors and also the at least one further, front-side subcell is grown and stabilised at the front-side on a carrier (e.g. made of sapphire) by means of detachable adhesive. These two subcell structures are then connected by means of wafer bonding between the second and third subcell. Subsequently, the carrier and the adhesive are removed.

2. On the first germanium subcell, the metamorphic buffer layer and the second subcell are grown. Separately herefrom on a GaAs- or Ge substrate, the at least one further, front-side subcell and the third subcell made of III-V semiconductors are grown in an inverted manner. These two subcell structures are subsequently connected by means of wafer bonding between the second and third subcell. Finally, the GaAs- or Ge substrate is detached.

3. On GaAs- or Ge substrate, the at least one further, front-side subcell is grown. Subsequently, on the side, orientated away from the GaAs- or Ge substrate, of the at least one front-side subcell, the third subcell made of III-V semiconductors is grown. On the third subcell, on the side orientated away from the at least one further front-side subcell, the metamorphic buffer layer and the second subcell are grown. This subcell structure is connected, on the surface of the second subcell, to a first, separately produced germanium subcell by means of wafer bonding. Subsequent to the wafer bonding, detachment of the GaAs- or Ge substrate is then effected.

What is new in this approach is that a GaInAs subcell having an optimum band gap energy of 1.0 eV can be integrated in a conventional solar cell structure made of GaInP/GaAs/germanium via wafer bonding and with metamorphic buffer growth. As a result, the growth method of organometallic vapour phase epitaxy with its proven low costs can be used. Furthermore, the structure profits from the high radiation stability of the germanium lower cell for space application. The processing of multi junction solar cells on germanium is furthermore already established in the industry, just as processing of the front-side. Existing production processes can be used herewith. The described approach is also particularly economical and interesting with respect to costs if a detachment method for the GaAs substrate (necessary for growth of the upper subcells) can be found which makes it possible to recycle the substrate multi junction times for growth.

The solar cells according to the invention can be used both for space application and for application in terrestrial concentrator systems.

The present invention confers the advantage that established methods of organometallic vapour phase epitaxy can be used, which are based on epitaxial structures for GaInP, GaAs and germanium. Since also the production of the contacts on the rear-side of the germanium subcell and on the front-side are known and established, the conventional process chain can thus be retained so that the multi junction solar cell according to the invention can be easily integrated into the existing manufacturing technology. A further substantial advantage resides in the fact that the multi junction solar cell according to the invention has very high efficiency since the band gap energies of all the subcells can be adjusted such that these are close to the theoretical optimum. For space application, there is a further advantage since the germanium cell has a high radiation stability.

The subject according to the invention is intended to be explained in more detail with reference to the subsequent example and Figures without wishing to restrict said subject to the specific embodiments shown here.

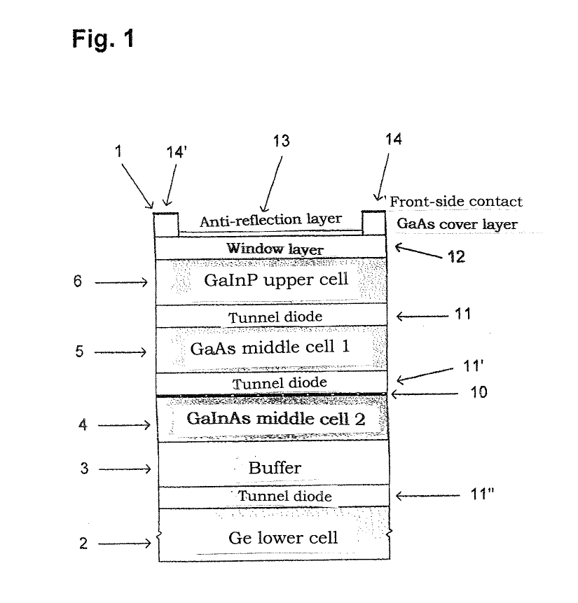

FIG. 1 shows a first embodiment of the multi junction solar cell according to the invention.

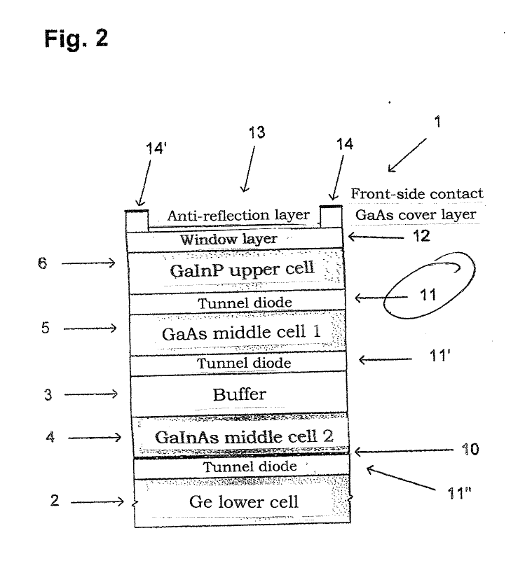

FIG. 2 shows a second embodiment of a multi junction solar cell according to the invention.

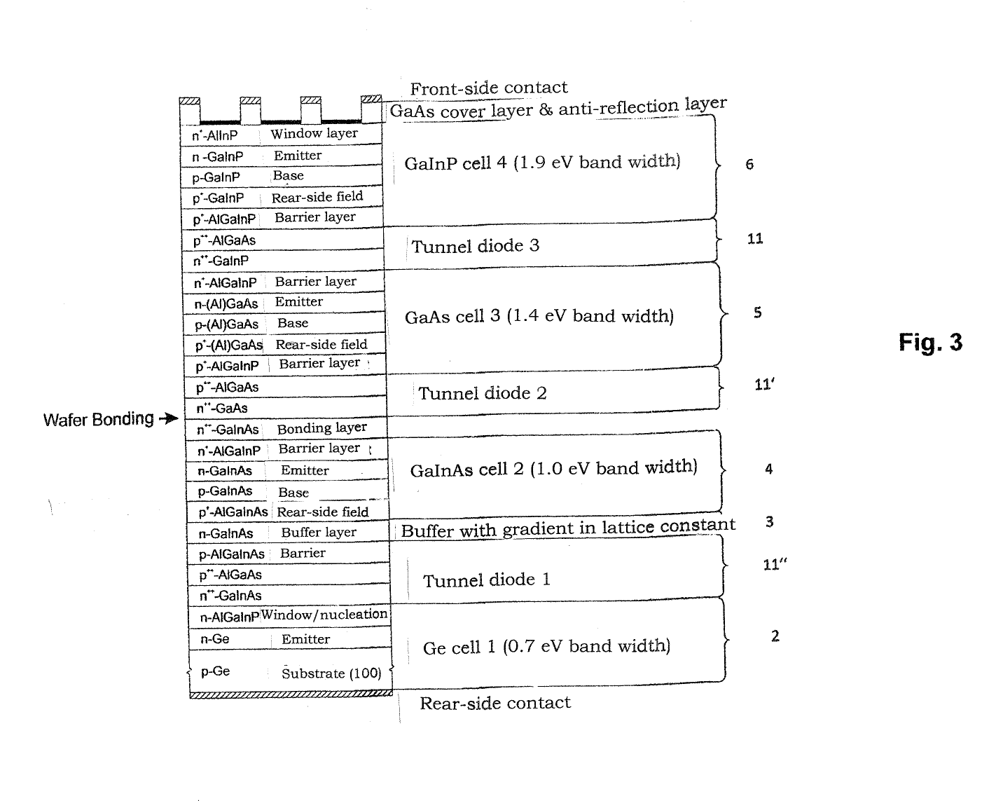

FIG. 3 shows a multi junction solar cell according to the invention having a large number of additional function-protection layers, in particular tunnel diodes and also barrier layers.

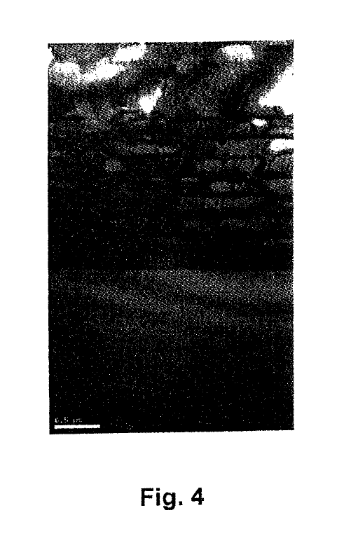

FIG. 4 shows a transmission electron microscope picture of the buffer layer according to the invention in which the lattice constant is changed from Ge up to Ga_{0.71}In_{0.29}As.

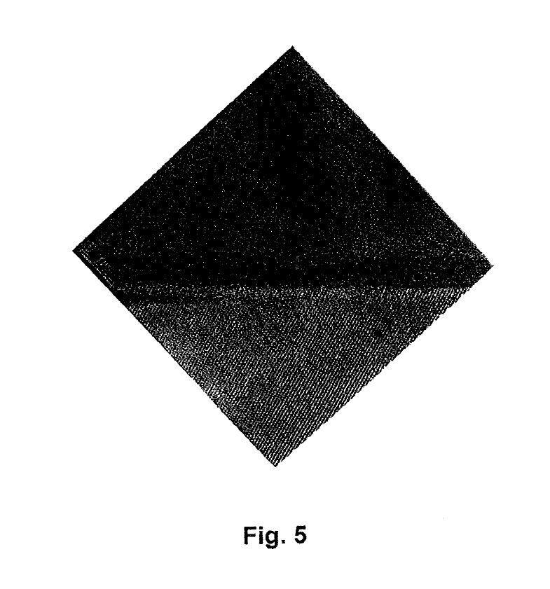

FIG. 5 shows a wafer-bonding connection according to the invention between two semicondictors having different lattice constants.

In FIG. 1, a multi junction solar cell 1 having a rear-side germanium subcell 2 is illustrated. On this subcell, a metamorphic buffer 3 and the second subcell made of GaInAs is grown. The second subcell is connected to a third subcell 5 made of gallium arsenide via a wafer bonding 10. The multi junction solar cell has a further, front-side subcell 6 made of GaInP. Furthermore, tunnel diodes 11, 11′ and 11″ are integrated in the multi junction solar cell for the electrical connection of the subcells. On the front-side, the multi junction solar cell has a window layer 12, an anti-reflection layer 13 and also front-side contacts 14 and 14′.

In FIG. 2, a second embodiment of the multi junction solar cell 1 according to the invention is illustrated. This multi junction solar cell is based on the inverted growth of the structure. The upper part of the multi junction solar cell 1, i.e. the subcell 6 made of GaInP and the subcell 5 made of GaAs, is thereby grown firstly on a substrate made of gallium arsenide in an inverted manner. Subsequently, the metamorphic buffer 3 and the second subcell 4 made of GaInAs are grown. The metamorphic buffer 3 thereby serves for conversion of the lattice constant from GaAs to GaInAs. The rear-side germanium subcell 2 is produced separately and is subsequently connected to the inversely grown solar cell structure made of GaInP/GaAs/GaInAs via the wafer bonding 10. Furthermore, tunnel diodes 11, 11′ and 11″ are integrated in the multi junction solar cell 1 for the electrical connection of the metal cells. The multi junction solar cell 1 has furthermore a window layer 12, an anti-reflection layer 13 and also front-side contacts 14 and 14′.

### Example

A multi junction solar cell 1 according to the invention is shown in FIG. 3. Firstly a layer sequence is hereby produced on Ge with a lattice constant of 5.65 Angström. For this purpose, the Ge subcell 1 is produced by diffusion and growth of an AlGaInP window layer in the MOVPE reactor. On the Ge subcell 2, a tunnel diode 11″ made of degenerate n- and p-conducting semiconductor layers is grown. The tunnel diode can be surrounded by further barrier layers having higher band gap energy. Thereafter follows a GaInP buffer layer 3 in which the lattice constant is converted from Ge up to Ga_{0.71}In_{0.29}As having a band gap energy of 1.0 eV. A transmission electron microscope picture of such a buffer layer is shown in FIG. 4. Because of the difference in the lattice constant of 2.3%, defective adaptation offsets which run horizontally through the buffer layer are produced. These can be seen as dark lines in the TEM picture. By means of a suitable choice of growth conditions, the density of penetrating offsets can be kept so low that solar cells of good quality can still be produced on the buffer layers. After the buffer layer, the Ga_{0.71}In_{0.29}As subcell 4 having a lattice constant of 5.78 Angström is made epitaxial. The subcell consists of a p-conducting base, an n-conducting emitter and further barrier layers for minority charge carriers on the front-side and rear-side. A highly doped n-Ga_{0.71}In_{0.29}As bonding layer follows on the Ga_{0.71}In_{0.29}As subcell 4.

A second layer sequence is deposited on a separate GaAs or Ge substrate. This comprises firstly a detachment layer which can be used subsequently for separating the substrate from the solar cell structure. An example is an AlAs intermediate layer which can be etched in hydrofluoric acid selectively relative to the remaining layers. Following thereon is a GaAs contact layer with high doping, a subcell 6 made of Ga_{0.5}In_{0.5}P, a tunnel diode 11, a GaAs or AlGaAs subcell 5 and a tunnel diode 11′. The subcells and tunnel diodes can, as in the case of the subcell 4 and the tunnel diode 11″, comprise additional barrier layers having higher band gap energy. All the semiconductor layers of the layer sequence are adapted lattice-wise to each other and have a lattice constant of approx. 5.65 Angström.

The two layer structures are now connected to each other via a wafer bonding. A direct bonding which fulfils the properties of transparency and very good conductivity is particularly suitable hereby. In a possible process, the two layer structures are de-oxidised in a vacuum whilst being bombarded with Ar atoms. A 1-3 nm thin amorphous layer is thereby produced on the surface. The two layer structures are subsequently pressed together at room temperature at a pressure of 5-10 kNewton. In order to increase the bonding energy, further heating at temperatures of 100-500° C. can be necessary. Furthermore, it is necessary to polish the surface of the layer structures if the surface roughness is worse than 1 nm. Such a direct wafer bonding between two semiconductors having a different lattice constant is shown in FIG. 5 in a transmission electron microscope picture. The amorphous intermediate layer at the bonding interface can be seen.

After the wafer bonding, the GaAs or Ge substrate is removed from the layer structure and the solar cell is processed with contacts and anti-reflection layers.

The research work which led to these results was sponsored by the European Union.

1. A multi junction solar cell having at least four p-n junctions comprising a first, rear-side germanium subcell which has a p-n junction, a second and a third subcell made of III-V semiconductors and also at least one further, front-side subcell made of III-V semiconductors,
wherein the second subcell has a lattice constant which is greater by at least 1% than the lattice constant of all the other subcells and the second subcell is connected to the adjacent subcells via a metamorphic buffer layer for adaptation to the lattice constant of the adjacent subcells and, on the opposite side, is connected to the adjacent subcell via a wafer-bonding connection.

2. The multi junction solar cell according to claim 1,
wherein the second subcell consists of GaInAs, GaInAsP, AlGaInAs, or GaAsSb.

3. The multi-junction solar cell according to claim 1,
wherein the second subcell has a band gap energy between 0.7 eV and 1.4 eV.

4. The multi-junction solar cell according to claim 1,
wherein the second subcell has a lattice constant which is greater by 1.5% to 3%, than the lattice constants of all the other subcells.

5. The multi junction solar cell according to claim 1,
wherein the metamorphic buffer layer consists of GaInAs, AlGaInAs, GaInP, AlGaInP, GaAsSb, AlAsSb, GaPSb or AlPSb.

6. The multi-junction solar cell according to claim 1,
wherein the wafer-bonding connection is electrically conductive and optically transparent.

7. The multi-junction solar cell according to claim 1,
wherein the third subcell consists of GaAs, GaInAs or AlGaInAs.

8. The multi-junction solar cell according to claim 1,
wherein at least one further subcell consists of GaInP, AlGaAs or AlGaInP.

9. The multi-junction solar cell according to claim 1,
wherein at least one further subcell consists of a front-side subcell and optionally at least one subcell disposed between the third and the front-side subcell.

10. The multi-junction solar cell according to claim 1,
wherein the individual subcells have further function-protection layers.

11. A method for the production of a multi-junction solar cell according to claim 1, in which
a) on the first germanium subcell, the metamorphic buffer layer and the second subcell are grown,
b) on a GaAs- or Ge substrate, the third subcell made of III-V semiconductors and also the at least one further, front-side subcell are grown, subsequently the structure at the front-side is stabilised by a carrier by means of detachable adhesive and the GaAs- or Ge substrate is removed,
c) the subcell structures from a) and b) are connected by means of wafer bonding between the second and third subcell, and
d) the carrier and the adhesive are removed,
wherein the second subcell is grown with a lattice constant which is greater by at least 1% than the lattice constants of all the other subcells.

12. The method for the production of a multi-junction solar cell according to claim 1, in which
a) on the first germanium subcell, the metamorphic buffer layer and the second subcell are grown,
b) on a GaAs- or Ge substrate, the at least one further, front-side subcell and subsequently the third subcell made of III-V semiconductors are grown in an inverted manner,
c) the subcell structures from a) and b) are connected by means of wafer-bonding between the second and third subcell, and
d) after the wafer bonding, the GaAs- or Ge substrate is detached,
wherein the second subcell is grown with a lattice constant which is greater by at least 1% than the lattice constants of all the other subcells.

13. The method for the production of a multi-junction solar cell according to claim 1, in which
a) on a GaAs- or Ge substrate, the at least one further, front-side subcell and, on the side, orientated away from the GaAs- or Ge substrate, of the at least one, front-side subcell, the third subcell made of III-V semiconductors is grown,
b) on the third subcell, on the side orientated away from the at least one further, front-side subcell, the metamorphic buffer layer and the second subcell are grown,
c) the subcell structure from b) is connected on the surface of the second GaInAs subcell to the first germanium subcell by means of wafer-bonding, and
d) after the wafer-bonding, the GaAs- or Ge substrate is detached,
wherein the second subcell is grown with a lattice constant which is greater by at least 1% than the lattice constants of all the other subcells.

14. The method according to claim 11,
wherein the growth of the second subcell, of the third subcell and of the at least one further, front-side subcell is effected epitaxially and the growth of the metamorphic buffer layer is effected metamorphically.

15. A method of converting light into electrical energy comprising utilizing the multi junction solar cell according to claim 1 in space or in terrestrial concentrator systems.

16. The multi-junction solar cell according to claim 2, wherein the indium content of GaInAs, GaInAsP, or AlGaInAs, relative to the group III elements, is 10% to 80%, or the antimony content, relative to the group V elements, of GaAsSb is 13% to 50%.

17. The multi-junction solar cell according to claim 3, wherein the second subcell has a band gap energy between 0.9 eV and 1.1 eV.

18. The multi junction solar cell according to claim 4, wherein the second subcell has a lattice constant which is greater by 2% to 2.5%, than the lattice constants of all the other subcells.

19. The multi-junction solar cell according to claim 2, wherein the metamorphic buffer layer consists of GaInAs, AlGaInAs, GaInP, AlGaInP, GaAsSb, AlAsSb, GaPSb or AlPSb.

20. The multi junction solar cell according to claim 3, wherein the metamorphic buffer layer consists of GaInAs, AlGaInAs, GaInP, AlGaInP, GaAsSb, AlAsSb, GaPSb or AlPSb.

21. The multi junction solar cell according to claim 10, wherein the further function-protection layers are selected from tunnel diodes for the electrical connection of the individual subcells, barrier layers on the front- and rear-side of the subcells, highly doped contact layers, internal reflection layers, and anti-reflection layers on the front-side of the cell.
